(19) United States
(12) Patent Application Publication
(10) Pub. No.: US 2026/0293268 A1
(43) Pub. Date: Sep. 24, 2026

(54) LAMINATED STRUCTURE INCLUDING METAL SILICIDE, METHOD OF MANUFACTURING THE SAME, AND SEMICONDUCTOR DEVICE INCLUDING THE LAMINATED STRUCTURE

(71) Applicants: Samsung Electronics Co., Ltd., Suwon-si (KR); UNIVERSITY-INDUSTRY COOPERATION GROUP OF KYUNG HEE UNIVERSITY, Gyeonggi-do (KR)

(72) Inventors: Haeryong KIM, Suwon-si (KR); Woojin JEON, Yongin-si (KR); Byunghoon NA, Suwon-si (KR); Woonghyeon PARK, Suwon-si (KR); Jeonghyeon PARK, Yongin-si (KR); Jaeho LEE, Suwon-si (KR); Yoonah CHOI, Yongin-si (KR)

(73) Assignees: Samsung Electronics Co., Ltd., Suwon-si (KR); UNIVERSITY-INDUSTRY COOPERATION GROUP OF KYUNG HEE UNIVERSITY, Gyeonggi-do (KR)

(21) Appl. No.: 19/564,736

(22) Filed: Mar. 12, 2026

(30) Foreign Application Priority Data
Mar. 19, 2025 (KR) 10-2025-0035527

(51) Int. Cl. H10D 64/62; H10D 64/01; H10W 20/00; H10W 20/44

(52) U.S. Cl. CPC H10D 64/62; H10D 64/0112; H10W 20/066; H10W 20/4446; H10W 20/4451

(57) ABSTRACT

Provided are a laminated structure including a metal silicide, a method of manufacturing the laminated structure, and a semiconductor device including the laminated structure. The laminated structure includes an amorphous silicon layer, a metal silicide layer provided on the amorphous silicon layer, and a metal nitride layer provided on the metal silicide layer.

### CROSS-REFERENCE TO RELATED APPLICATION

This application is based on and claims priority under 35 U.S.C. § 119 to Korean Patent Application No. 10-2025-0035527, filed on Mar. 19, 2025, in the Korean Intellectual Property Office, the disclosure of which is incorporated by reference herein in its entirety.

### BACKGROUND

### 1. Field

The disclosure relates to a laminated structure including a metal silicide, a method of manufacturing the laminated structure, and a semiconductor device including the laminated structure.

### 2. Description of the Related Art

Current (e.g., the rate of flow of electrical conductors through a structure) is a contributing factor in determining the operation speed of semiconductor devices, and thus, it may be beneficial to reduce and/or protect against phenomena that may reduce the current in said semiconductor devices. For example, reducing the contact resistance between layers that are in physical and electrical contact with each other may increase the operation speed of the semiconductor devices. For example, when electrically connecting metal wiring lines to each other, high contact resistance may occur at an electrical connection formed by bringing a source/drain electrode containing a metal into contact with a source/drain region containing silicon, or an electrical connection formed by bringing a wiring line containing a metal into contact with a gate electrode containing silicon. Metal silicides, which are metal-silicon compounds, may be used in various fields to address such contact resistance issues.

### SUMMARY

Provided are a laminated structure including a metal silicide, a method of manufacturing the laminated structure, and a semiconductor device including the laminated structure.

Additional aspects will be set forth in part in the description which follows and, in part, will be apparent from the description, or may be learned by practice of the presented embodiments of the disclosure.

According to an aspect of the disclosure, a laminated structure includes: an amorphous silicon layer; a metal silicide layer on the amorphous silicon layer; and a metal nitride layer on the metal silicide layer such that the metal silicide layer is between the metal nitride layer and the amorphous silicon layer.

The metal silicide layer may be a structure including one or more layers.

The metal silicide layer may include at least one of TiSiₓ, ZrSiₓ, MoSiₓ, WSiₓ, CoSiₓ, or NiSiₓ.

The metal nitride layer may include at least one of TiN, TaN, WN, or NbN.

The amorphous silicon layer may have a thickness of about 0.1 nanometers (nm) to about 50 nm.

The metal silicide layer may have a thickness of about 0.1 nm to about 20 nm.

The metal nitride layer may have a thickness of about 0.1 nm to about 10 nm.

The laminated structure may further include a first material layer on a lower surface of the amorphous silicon layer, and a second material layer on an upper surface of the metal nitride layer.

The first material layer may include at least one of a semiconductor material or a metal.

The second material layer may include a metal.

According to another aspect of the disclosure, a method of manufacturing a laminated structure includes: depositing an amorphous silicon layer on a first material layer; depositing a metal layer on the amorphous silicon layer; depositing a metal nitride layer on the metal layer; and forming a metal silicide layer between the amorphous silicon layer and the metal nitride layer by forming a compound of a metal of the metal layer and silicon of the amorphous silicon layer using a heat treatment process.

The depositing the metal layer may be performed in situ on the amorphous silicon layer, and the depositing the metal nitride layer may be performed in situ on the metal layer.

The heat treatment process may be performed at a temperature of 500° C. or higher.

The first material layer may include at least one of a semiconductor material or a metal.

The method may further include forming a second material layer on the metal nitride layer.

The second material layer may include a metal.

According to another aspect of the disclosure, a semiconductor device includes: a semiconductor layer including silicon; an amorphous silicon layer on the semiconductor layer; a metal silicide layer on the amorphous silicon layer; a metal nitride layer on the metal silicide layer; and a metal layer on the metal nitride layer.

The semiconductor layer may include a source or drain region of a channel layer, and the metal layer may include a source or drain electrode.

The semiconductor layer may include a gate electrode, and the metal layer may include a metal wiring line.

The metal silicide layer may include at least one of TiSiₓ, ZrSiₓ, MoSiₓ, WSiₓ, CoSiₓ, or NiSiₓ.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a laminated structure according to at least one example embodiment;

FIG. 2 is a cross-sectional view illustrating a laminated structure according to at least one example embodiment;

FIGS. 3 to 9 are views illustrating a method of manufacturing a laminated structure according to at least one example embodiment;

FIG. 10A is a transmission electron microscope (TEM) image illustrating a cross-section of a laminated structure (amorphous silicon (a-Si) layer/metal (Ti) layer/metal nitride (TiN) layer) before a heat treatment process in a method of manufacturing a laminated structure, according to at least one example embodiment;

FIG. 10B is a TEM image illustrating a cross-section of a laminated structure (amorphous silicon (a-Si) layer/metal silicide (TiSiₓ) layer/metal nitride (TiN) layer) after a heat treatment process in a method of manufacturing a laminated structure, according to at least one example embodiment;

FIG. 11 is a graph illustrating results of X-ray diffraction (XRD) analysis of a laminated structure after a heat treatment process, measured for different thicknesses of an amorphous silicon (a-Si) layer prior to the heat treatment process;

FIG. 12 is a graph illustrating results of XRD analysis of a laminated structure after a heat treatment process, measured for different thicknesses of a metal nitride (TiN) layer prior to the heat treatment process;

FIGS. 13A and 13B are TEM images for comparing a surface of a metal nitride (TiN) layer before and after a heat treatment process in a method of manufacturing a laminated structure, according to at least one example embodiment;

FIG. 14 is a graph illustrating results of XRD analysis of a laminated structure after a heat treatment process, measured for different temperatures of the heat treatment process;

FIG. 15 is a view schematically illustrating a semiconductor device according to at least one example embodiment; and

FIG. 16 is a view schematically illustrating a semiconductor device according to at least one example embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects.

Hereinafter, example embodiments will be described with reference to the accompanying drawings. In the drawings, like reference numerals refer to like elements, and the sizes of elements may be exaggerated for clarity of illustration. The embodiments described herein are for illustrative purposes only, and various modifications may be made therein. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values.

In the following description, when an element is referred to as being “above” or “on” another element, it may be directly on an upper, lower, left, or right side of the other element while making contact with the other element or may be above an upper, lower, left, or right side of the other element without making contact with the other element. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary, and are not limited to the stated order thereof.

In the disclosure, the use of terms like “. . . unit”, “. . . module”, etc., which are used herein specify a unit for processing at least one function or operation, may be implemented with and/or include processing circuitry such as hardware or software or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Also, connecting lines or connecting members illustrated in the drawings are intended to represent example functional relationships and/or physical or logical connections between the various elements. It should be noted that many alternative or additional functional relationships, physical connections or logical connections may be present in a practical device.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples or terms are just used herein to describe technical ideas and should not be considered for purposes of limitation unless defined by the claims.

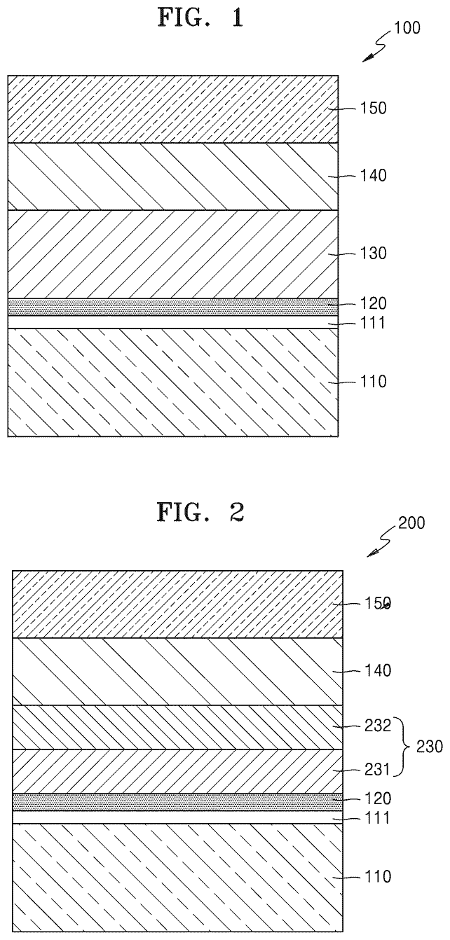

FIG. 1 is a cross-sectional view illustrating a laminated structure 100 according to at least one example embodiment.

Referring to FIG. 1, the laminated structure 100 includes an amorphous silicon layer 120, a metal silicide layer 130, and a metal nitride layer 140 that are sequentially stacked. The amorphous silicon layer 120 may be provided above a first material layer 110. In at least some example embodiments, the first material layer 110 may include a semiconductor material. For example, the first material layer 110 may include an elemental semiconductor (such as crystalline silicon (Si)) and/or a compound semiconductor. For example, in a semiconductor device such as a field effect transistor (FET), the first material layer 110 may form a doped source (or drain region) that is in contact with a source (or drain) electrode. In addition, the first material layer 110 may form a gate electrode including polycrystalline silicon (poly silicon). However, these are only examples, and the first material layer 110 may include various materials other than silicon. For example, in at least one example, the first material layer 110 may include a metal and/or a conductive material (such as a zero-band gap material and/or a fermi level in a conductive band).

An oxide layer 111 may be formed on an upper surface of the first material layer 110. For example, when the first material layer 110 includes crystalline silicon, a silicon oxide layer may be formed by oxidation of the crystalline silicon may be provided on the upper surface of the first material layer 110. However, the example embodiments are not limited thereto, and another oxide layer may be formed on the upper surface of the first material layer 110. In addition, the oxide layer 111 may not be formed on the upper surface of the first material layer 110.

The amorphous silicon layer 120 is provided above the first material layer 110. In a method of manufacturing the laminated structure 100, which will be described later, the amorphous silicon layer 120 may serve to supply silicon for the formation of the metal silicide layer 130, and may also serve to protect against the oxygen remaining in the first material layer 110 from diffusing into a metal layer 135 (refer to FIG. 5) and the metal nitride layer 140. The amorphous silicon layer 120 may have a thickness of, for example, about 0.1 nanometers (nm) to about 50 nm, but is not limited thereto. For example, the amorphous silicon layer 120 may have a thickness of about 0.1 nm to about 5 nm.

The metal silicide layer 130 may be provided on the amorphous silicon layer 120. In a method of manufacturing the laminated structure 100, which will be described later, a metal of the metal layer 135 (refer to FIG. 5) and silicon of the amorphous silicon layer 120 may combine with each other to form a compound, and the metal silicide layer 130 may be formed by the compound. Metal silicides are chemically stable materials that may reduce (e.g., decrease) contact resistance between metal materials and/or between a semiconductor material and a metal.

The metal silicide layer 130 may include, for example, a transition metal. For example, the metal silicide layer 130 may include at least one of TiSiₓ, ZrSiₓ, MoSiₓ, WSiₓ, CoSiₓ, and/or the like (where x refers to 2 or a positive number about 2). In addition, the metal silicide layer 130 may include, for example, NiSiₓ (where x refers to 1 or a positive number about 1). However, these are only examples, and the metal silicide layer 130 may include various other materials. The metal silicide layer 130 may have, for example, a thickness of about 20 nm or less. For example, the metal silicide layer 130 may have a thickness of about 0.1 nm to about 20 nm.

The metal nitride layer 140 is provided on the metal silicide layer 130. The metal nitride layer 140 may include a conductive metal nitride. For example, the metal nitride layer 140 may include at least one of TiN, TaN, WN, NbN, and/or the like. However, these are only some examples, and the metal nitride layer 140 may include various other metal nitrides. The metal nitride layer 140 may have, for example, a thickness of about 10 nm or less. For example, the metal nitride layer 140 may have a thickness of about 0.1 nm to about 10 nm. However, example embodiments are not limited thereto. In addition, the metal nitride layer 140 may further include oxygen introduced from the outside during the manufacture of the laminated structure 100.

A second material layer 150 may be provided on the metal nitride layer 140. The second material layer 150 may include, for example, a metal and/or a conductive material. For example, in a semiconductor device such as an FET, the second material layer 150 may form a source or drain electrode that is in contact with a source region or a drain region. In addition, the second material layer 150 may form a metal wiring line electrically connected to a gate electrode.

FIG. 2 is a cross-sectional view illustrating a laminated structure 200 according to at least one example embodiment. The laminated structure 200 shown in FIG. 2 is the same as (or substantially similar to) the laminated structure 100 shown in FIG. 1 except that a metal silicide layer 230 has a multilayer structure. Therefore, the differences from the previous embodiment will mainly be described hereinafter.

Referring to FIG. 2, the laminated structure 200 includes a first material layer 110, an amorphous silicon layer 120, the metal silicide layer 230, a metal nitride layer 140, and a second material layer 150 that are sequentially stacked. The first material layer 110 may include, for example, a semiconductor material and/or a conductive material. The second material layer 150 may include, for example, a conductive material.

The amorphous silicon layer 120 is provided above the first material layer 110. The metal silicide layer 230 is provided on the amorphous silicon layer 120. Here, the metal silicide layer 230 has a multilayer structure. For example, the metal silicide layer 230 may include a first silicide layer 231 provided on an upper surface of the amorphous silicon layer 120, and a second silicide layer 232 provided on an upper surface of the first silicide layer 231. Here, the first and second silicide layers 231 and 232 may include different metal silicide materials. For example, each of the first and second silicide layers 231 and 232 may include at least one of TiSiₓ, ZrSiₓ, MoSiₓ, WSiₓ, CoSiₓ, or the like (where x refers to 2 or a positive number about 2), or may include NiSiₓ (where x refers to 1 or a positive number about 1). However, the example embodiments are not limited thereto. For example, the first silicide layer 231 may include ZrSiₓ, and the second silicide layer 232 may include TiSiₓ. However, this is only an example.

The metal nitride layer 140 is provided on the metal silicide layer 230. The metal nitride layer 140 may include, for example, at least one of TiN, TaN, WN, or NbN. However, these are only examples.

In the at least example embodiment described above, the metal silicide layer 230 includes two silicide layers (the first and second silicide layers 231 and 232) containing different materials. However, the example embodiments are not limited thereto, and the metal silicide layer 230 may include three or more silicide layers containing different materials.

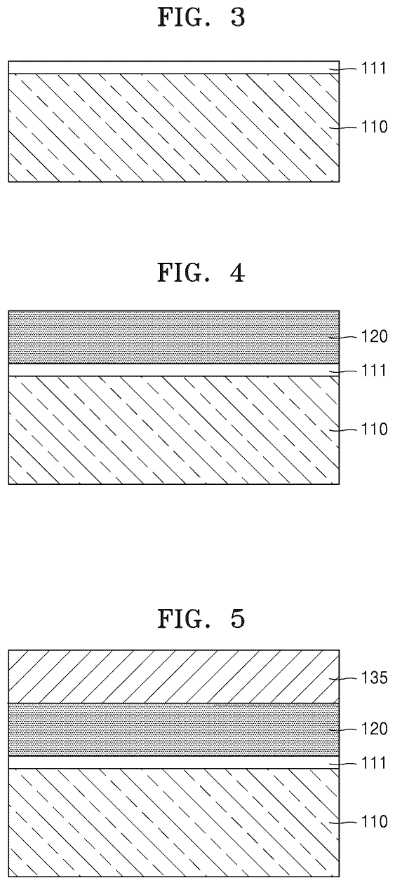

FIGS. 3 to 9 are views illustrating a method of manufacturing a laminated structure 100 according to at least one example embodiment. In the method of manufacturing the laminated structure 100 shown in FIGS. 3 to 9, for example, physical vapor deposition (PVD) may be used to deposit each layer. However, this is only an example, and various other deposition methods may also be used.

First, referring to FIG. 3, a first material layer 110 is prepared. The first material layer 110 may include a semiconductor material and/or a conductive material. For example, the first material layer 110 may include crystalline silicon. For example, in a semiconductor device such as an FET, the first material layer 110 may form a doped source or drain region that is in contact with a source or drain electrode. In addition, the first material layer 110 may form a gate electrode including polycrystalline silicon. However, these are only examples, and the first material layer 110 may include various semiconductor materials other than silicon. In at least some example embodiments, the first material layer 110 may include a metal.

An oxide layer 111 may be formed on an upper surface of the first material layer 110. For example, when the first material layer 110 includes crystalline silicon, a silicon oxide layer formed by oxidizing the crystalline silicon may be provided on the upper surface of the first material layer 110. However, the example embodiments are not limited thereto, and another oxide layer may be formed on the upper surface of the first material layer 110. In addition, the oxide layer 111 may not be formed on the upper surface of the first material layer 110.

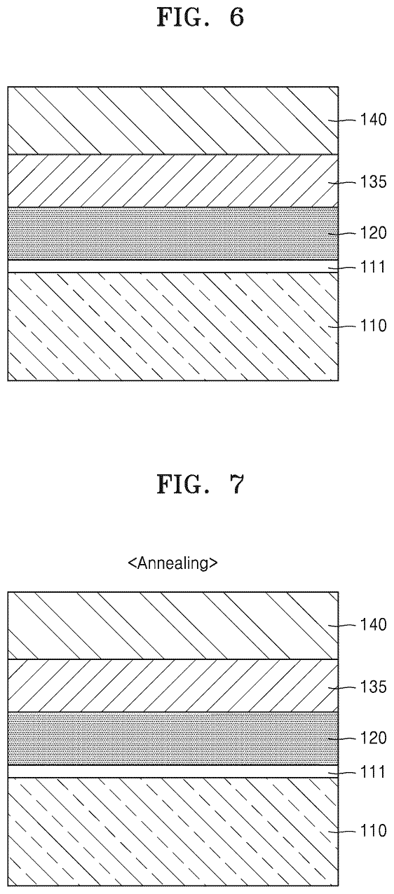

Referring to FIG. 4, an amorphous silicon layer 120 is deposited above the first material layer 110. The amorphous silicon layer 120 may serve to supply silicon for the formation of a metal silicide layer 130 (described later), and may also serve to protect against (e.g., prevent and/or mitigate against) the oxygen remaining in the first material layer 110 from diffusing into a metal layer 135 (refer to FIG. 5) and a metal nitride layer 140 (refer to FIG. 6) that are provided above the amorphous silicon layer 120. In other words, the amorphous silicon layer 120 may be referred to as protecting the metal layer 135 (refer to FIG. 5) and/or the metal nitride layer 140 (refer to FIG. 6) from being oxidized by the diffusion of oxygen out of the first material layer 110. Here, the amorphous silicon layer 120 may be thicker than the amorphous silicon layer 120 of the laminated structure 100 shown in FIG. 1. For example, the thickness of the amorphous silicon layer 120 may be greater than about 0.1 nm, but is not limited thereto.

Referring to FIG. 5, the metal layer 135 is deposited on the amorphous silicon layer 120. Here, the metal layer 135 may be deposited in situ on the amorphous silicon layer 120. The metal layer 135 may have a function of supplying a metal for the formation of the metal silicide layer 130 (described later). The metal layer 135 may include, for example, a transition metal. For example, the metal layer 135 may include at least one of Ti, Zr, Mo, W, Co, Ni, or the like. However, these are only examples, and the metal layer 135 may include various other metals. The metal layer 135 may have an appropriate thickness for the formation of the metal silicide layer 130.

Referring to FIG. 6, the metal nitride layer 140 is formed on the metal layer 135. The metal nitride layer 140 may be deposited in situ on the metal layer 135. The metal nitride layer 140 may include a conductive material, such as a conductive metal nitride. For example, the metal nitride layer 140 may include TiN, TaN, WN, or NbN. However, these are only examples, and the metal nitride layer 140 may include various other metal nitrides. For example, the metal nitride layer 140 may have a thickness of about 10 nm or less. For example, the metal nitride layer 140 may have a thickness of about 0.1 nm to about 10 nm. However, embodiments are not limited thereto.

Referring to FIG. 7, a heat treatment process is performed on a structure shown in FIG. 6. The heat treatment process may include annealing the structure. The heat treatment process may be performed, for example, at a temperature of about 500° C. or higher. For example, the heat treatment process may be performed at a temperature of about 500° C. to about 700° C. However, embodiments are not limited thereto.

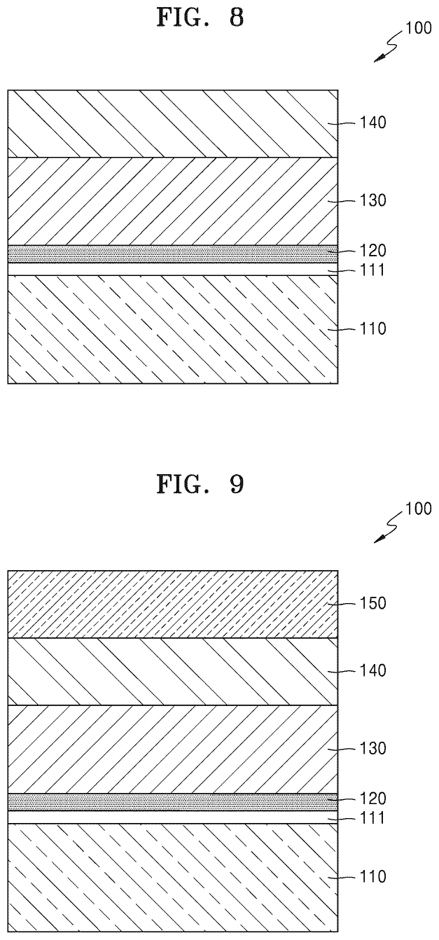

Owing to the heat treatment process described above, silicon included in the amorphous silicon layer 120 and a metal included in the metal layer 135 may combine to form a metal silicide, which is a metal-silicon compound, and thus, as shown in FIG. 8, the metal silicide layer 130 may be formed between the amorphous silicon layer 120 and the metal nitride layer 140. The metal silicide layer 130 may include, for example, at least one of TiSiₓ, ZrSiₓ, MoSiₓ, WSiₓ, CoSiₓ, or the like (where x refers to 2 or a positive number about 2). The metal silicide layer 130 may include, for example, NiSiₓ (where x refers to 1 or a positive number about 1). However, these are only examples, and the metal silicide layer 130 may include various other materials. For example, the metal silicide layer 130 may a thickness of about 20 nm or less. For example, the metal silicide layer 130 may have a thickness of about 0.1 nm to about 20 nm. For example, the amorphous silicon layer 120 provided below the metal silicide layer 130 may have a thickness of about 0.1 nm to about 50 nm (for example, about 0.1 nm to about 5 nm). However, the amorphous silicon layer 120 is not limited thereto.

In addition, during the formation of the metal silicide layer 130 through the heat treatment process, diffusion of external oxygen into the metal layer 135 may be prevented by the metal nitride layer 140, and the metal nitride layer 140 may contain oxygen introduced from the outside.

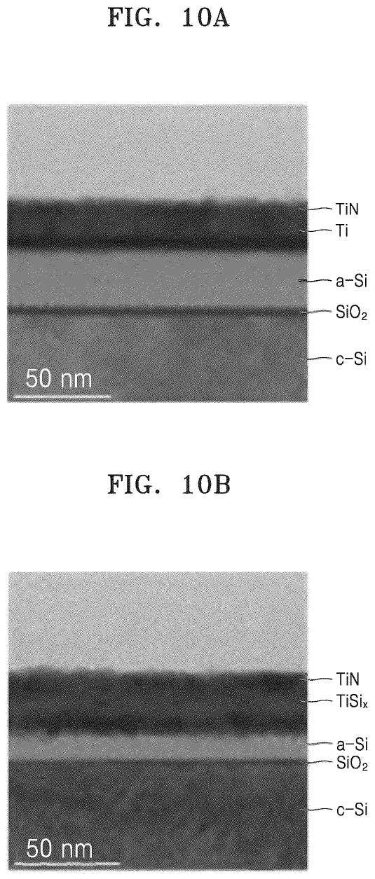

Referring to FIG. 9, a second material layer 150 is deposited on an upper surface of the metal nitride layer 140. The second material layer 150 may include, for example, a conductive material such as a metal. For example, in a semiconductor device such as an FET, the second material layer 150 may form a source or drain electrode that is in contact with a source or drain region. In addition, the second material layer 150 may form a metal wiring line electrically connected to a gate electrode.

In the description above, the heat treatment process for forming the metal silicide layer 130 is performed after depositing the metal nitride layer 140. However, the example embodiments are not limited thereto. For example, the heat treatment process for forming the metal silicide layer 130 may be performed after depositing the second material layer 150. Although it is described that the metal silicide layer 130 has a single-layer structure, the metal silicide layer 130 may have a multilayer structure in which two or more silicide layers including different materials are stacked.

In a comparative example, metal silicides, which are metal-silicon compounds, may be formed by performing an oxide layer and removal (deoxidation) process, a metal deposition process, and then a heat treatment process on an exposed surface of crystalline silicon. However, in such a metal silicide formation method, the deoxidation process performed on the surface of crystalline silicon may cause damage to other thin layers in the comparative example. In addition, during the heat treatment process performed after the metal deposition process, the metal may diffuse into the crystalline silicon and may undergo a channeling phenomenon in which the metal rapidly diffuses in directions of low atomic density, making it difficult to form a uniform interface.

In addition, relatively high heat treatment temperatures required to form metal silicides through diffusion and mixing of metal and silicon may negatively affect device characteristics. Furthermore, during the process of forming metal silicides through diffusion and mixing of metal and silicon, agglomeration of excess metal may occur, causing deterioration in the surface roughness of silicon silicides.

According to the example embodiments, after depositing the amorphous silicon layer 120, the metal layer 135 is deposited in situ, thereby eliminating the need for a deoxidation process and reducing damage to other thin layers in a device. The amorphous silicon layer 120 does not have specific directions of low atomic density associated with crystallinity, thereby preventing the occurrence of a channeling phenomenon. In addition, during the formation of the metal silicide layer 130 through the heat treatment process, the metal nitride layer 140 may prevent external oxygen from diffusing into the metal layer 135. Moreover, the metal nitride layer 140 may suppress the agglomeration of the metal layer 135, thereby preventing deterioration in the surface roughness of the metal silicide layer 130.

FIG. 10A is a transmission electron microscope (TEM) image illustrating a cross-section of the laminated structure 100 (amorphous silicon (a-Si) layer/metal (Ti) layer/metal nitride (TiN) layer) shown in FIG. 6 before the heat treatment process, in the method of manufacturing the laminated structure 100, according to the embodiment. FIG. 10B is a TEM image illustrating a cross-section of the laminated structure 100 (amorphous silicon (a-Si) layer/metal silicide (TiSiₓ) layer/metal nitride (TiN) layer) shown in FIG. 8 after the heat treatment process, in the method of manufacturing the laminated structure 100, according to the embodiment. Here, a single-crystalline silicon (c-Si) substrate was used as the first material layer 110, and the same applies hereinafter.

Referring to FIGS. 10A and 10B, it may be seen that, owing to the heat treatment process, the metal of the metal (Ti) layer and the silicon of the amorphous silicon (a-Si) layer combine to form a metal silicide (TiSiₓ), which is a metal-silicon compound.

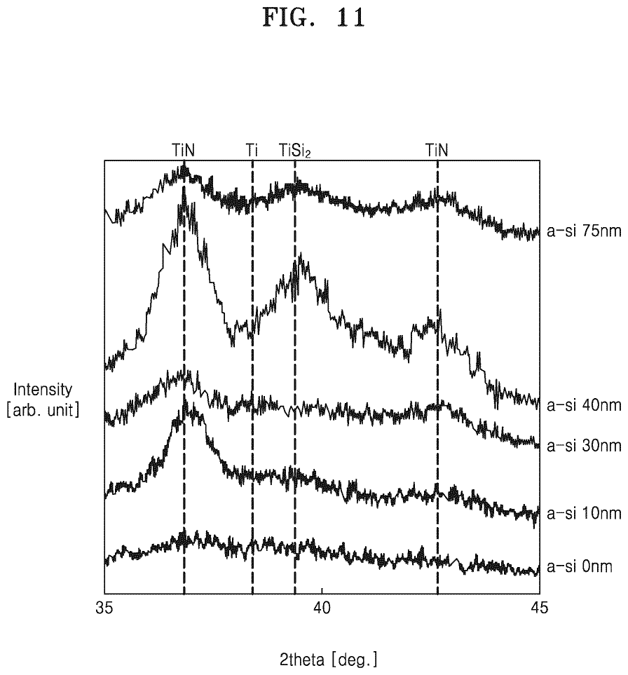

FIG. 11 is a graph illustrating results of X-ray diffraction (XRD) analysis of the laminated structure 100 after the heat treatment process, measured for different thicknesses of the amorphous silicon (a-Si) layer prior to the heat treatment process. FIG. 11 shows results of XRD analysis of the laminated structure 100 (amorphous silicon (a-Si) layer/metal silicide (TiSi₂)/metal nitride (TiN) layer) shown in FIG. 8 after the heat treatment process, measured for different thicknesses of the amorphous silicon (a-Si) layer (a-Si) of the laminated structure 100 (amorphous silicon (a-Si) layer/metal (Ti) layer/metal nitride (TiN) layer) shown in FIG. 6 before the heat treatment process.

Referring to FIG. 11, when there was no amorphous silicon layer (thickness of a-Si=0 nm), the formation of the metal silicide (TiSi₂) layer was not observed. That is, the metal silicide (TiSi₂) layer was not formed when the thickness of the amorphous silicon (a-Si) layer was less than a certain value. Furthermore, it may be understood that when the amorphous silicon (a-Si) layer (a-Si) has a sufficient thickness to prevent residual oxygen in the single-crystalline silicon substrate from diffusing into the metal (Ti) layer and the metal nitride (TiN) layer, the metal silicide (TiSi₂) layer is formed.

In results of XRD analysis conducted depending on the presence or absence of the metal (Ti) layer, the metal silicide (TiSi₂) layer was not formed when the thickness of the metal (Ti) layer was 0 nm. This shows that the metal nitride (TiN) layer does not contribute to the formation of metal silicide (TiSi₂). It was also confirmed that the metal silicide (TiSi₂) layer was formed only when the thickness of the metal (Ti) layer was equal to or greater than a certain value. When the metal (Ti) layer, which is deposited between the amorphous silicon (a-Si) layer and the metal nitride (TiN) layer for the formation of metal silicide (TiSi₂), has a thickness within a certain range, the metal (Ti) layer may be capable of supplying metal (Ti) for the formation of metal silicide (TiSi₂).

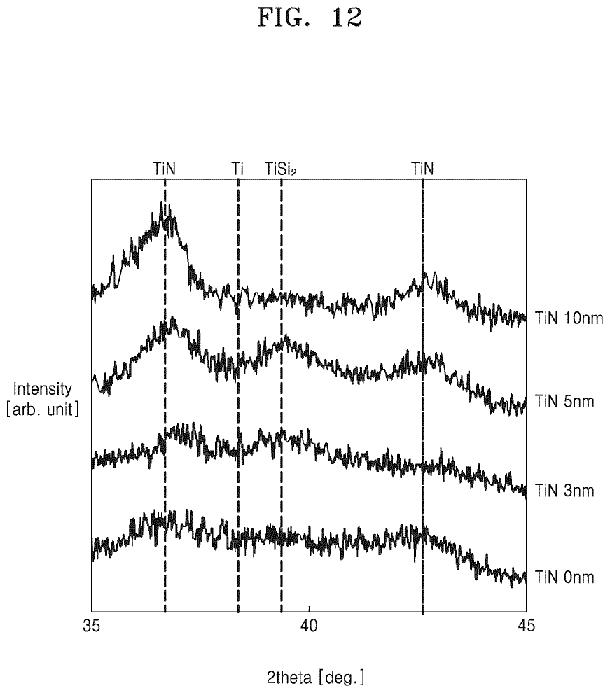

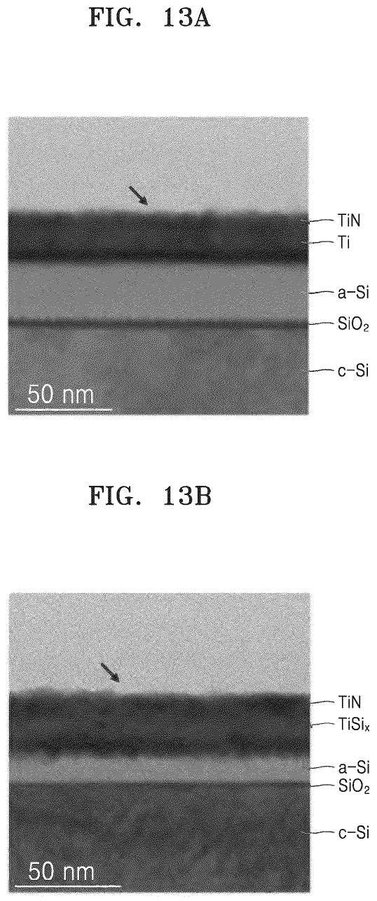

FIG. 12 is a graph illustrating results of XRD analysis of the laminated structure 100 after the heat treatment process, measured for different thicknesses of the metal nitride (TiN) layer prior to the heat treatment process. FIG. 12 shows results of XRD analysis of the laminated structure 100 (amorphous silicon (a-Si) layer/metal silicide (TiSi₂)/metal nitride (TiN) layer) shown in FIG. 8 after the heat treatment process, measured for different thicknesses of the metal nitride (TiN) layer of the laminated structure 100 (amorphous silicon (a-Si) layer/metal (Ti) layer/metal nitride (TiN) layer) shown in FIG. 6 before the heat treatment process.

Referring to FIG. 12, when the thickness of the metal nitride (TiN) layer was 0 nm, the formation of metal silicide (TiSi₂) was not observed, whereas when the thickness of the metal nitride (TiN) layer was greater than a certain value, the formation of the metal silicide (TiSi₂) was observed. This shows that the metal nitride (TiN) layer assists the formation of the metal silicide (TiSi₂) by effectively blocking the inflow of external oxygen. In addition, when the thickness of the metal nitride (TiN) layer was greater than an appropriate value, the formation of the metal silicide (TiSi₂) was not observed. This is because nitrogen diffusing from the metal nitride (TiN) layer converts the metal (Ti) layer into a metal nitride (TiN) layer.

In results of TEM analysis of the laminated structure 100 (amorphous silicon (a-Si) layer/metal silicide layer (TiSiₓ)/metal nitride (TiN) layer) shown in FIG. 8 after the heat treatment process, it was observed that substantially no oxygen was present in the amorphous silicon (a-Si) layer, unlike in the single-crystalline silicon (c-Si) substrate which contained a large amount of oxygen before the heat treatment process. In addition, it may be understood that the formation of the metal silicide (TiSiₓ) layer using the amorphous silicon (a-Si) layer effectively prevents a channeling phenomenon in which metal (Ti) rapidly diffuses in a certain direction inside the single-crystalline silicon (c-Si) substrate.

Furthermore, it was observed that after the heat treatment process, the metal nitride (TiN) layer contained a large amount of oxygen, whereas the metal silicide (TiSiₓ) layer contained substantially no oxygen. This shows that the metal nitride (TiN) layer effectively prevents external oxygen from penetrating into the metal (Ti) layer.

FIGS. 13A and 13B are TEM images for comparing a surface of the metal nitride (TiN) layer before and after the heat treatment process, in the method of manufacturing the laminated structure 100 according to the embodiment; FIG. 13A shows a surface of the laminated structure 100 (amorphous silicon (a-Si) layer/metal (Ti) layer/metal nitride (TiN) layer) shown in FIG. 6 before the heat treatment process, and FIG. 13B shows the surface of the laminated structure 100 (amorphous silicon (a-Si) layer/metal silicide (TiSiₓ) layer/metal nitride (TiN) layer) shown in FIG. 8 after the heat treatment process.

Referring to FIGS. 13A and 13B, the metal nitride (TiN) layer may suppress agglomeration of the metal (Ti) layer, and thus, deterioration in the surface roughness of the metal silicide (TiSiₓ) layer may be protected against. Therefore, it may be seen that the surface (indicated by arrows) of the metal nitride (TiN) layer shows little change before and after the heat treatment process.

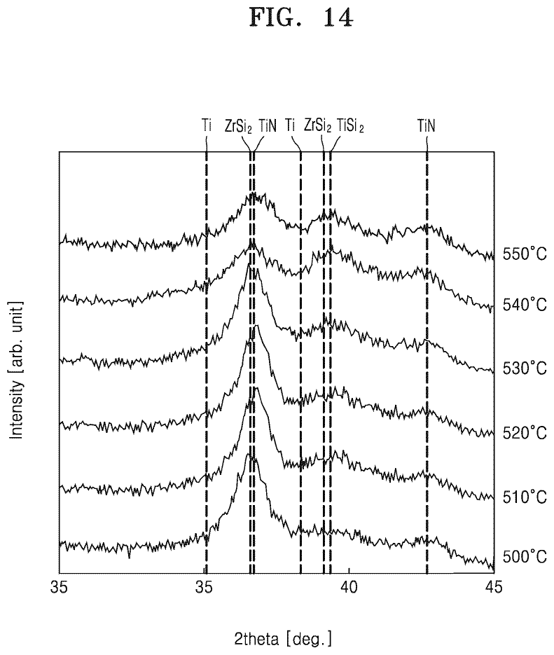

FIG. 14 shows results of XRD analysis of a laminated structure (amorphous silicon (a-Si) layer/metal silicide (ZrSi₂/TiSi₂) layer/metal nitride (TiN) layer) after a heat treatment process, measured for different temperatures of the heat treatment process. FIG. 14 shows results of analysis of the case in which the metal silicide layer includes two silicide layers (ZrSi₂/TiSi₂). Referring to FIG. 14, it was observed that when the temperature of the heat treatment process was 500° C. or higher, the metal silicide (ZrSi₂/TiSi₂) layer was formed.

The laminated structures 100 and 200 described above may be applied in various fields to reduce contact resistance. For example, the laminated structure 100 or 200 may be provided between a semiconductor and a metal or between metal wiring lines to reduce contact resistance. The laminated structures 100 and 200 may be applied to semiconductor devices such as transistors, memory devices such as dynamic random access memory (DRAM) devices, or various other devices.

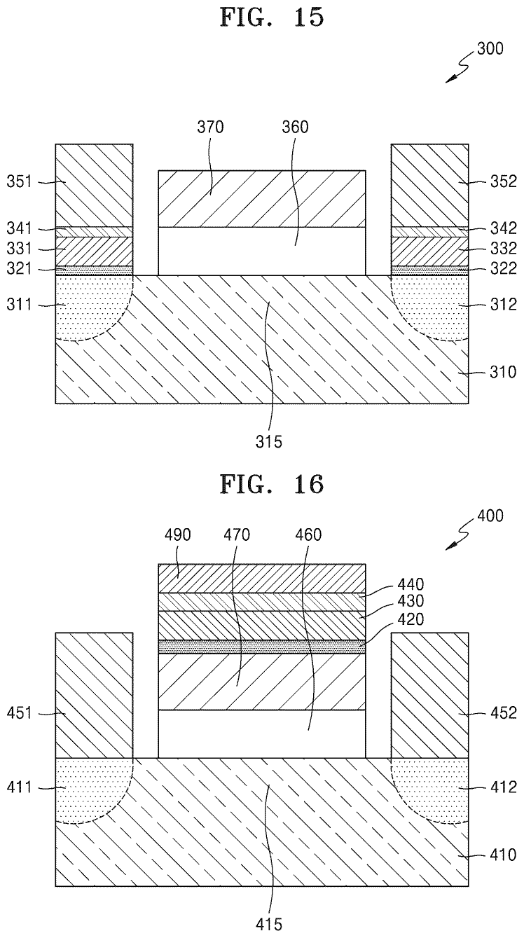

FIG. 15 is a view schematically illustrating a semiconductor device 300 according to at least one example embodiment. The semiconductor device 300 shown in FIG. 15 may be an FET.

Referring to FIG. 15, the semiconductor device 300 includes a substrate 310, a gate insulating layer 360, a gate electrode 370, a source electrode 351, and a drain electrode 352. The substrate 310 may include a semiconductor material. The substrate 310 may include, for example, Si, Ge, SiGe, a Group III-V semiconductor, and/or the like. The semiconductor substrate 310 may include, for example, an oxide semiconductor, a nitride semiconductor, an oxynitride semiconductor, a two-dimensional (2D) semiconductor material, a quantum dot, or an organic semiconductor. However, these are only examples, and embodiments are not limited thereto.

The substrate 310 may further include a dopant at a predetermined concentration. Here, the dopant may include a p-type dopant or an n-type dopant. Examples of the p-type dopant may include Group III elements such as B, Al, Ga, or In, and examples of the n-type dopant may include Group V elements such as P, As, or Sb.

A channel 315 corresponding to the gate electrode 370 is formed in an upper portion of the substrate 310. A source region 311 and a drain region 312 are respectively provided on both sides of the channel 315. The source region 311 and the drain region 312 may be formed by implanting a dopant into different regions of the substrate 310. The source region 311 may be electrically connected to one side of the channel 315, and the drain region 312 may be electrically connected to the other side of the channel 315. A region of the substrate 310 between the source region 311 and the drain region 312 may be defined as the channel 315. In addition, although the channel 315 is described as part of the substrate 310, the channel 315 may be formed as a separate material layer independent of the substrate 310.

The gate insulating layer 360 is provided on the channel 315 of the substrate 310, and the gate electrode 370 is provided on the gate insulating layer 360. The gate insulating layer 360 may include, for example, silicon oxide, silicon nitride, aluminum oxide, or the like, but is not limited thereto. The gate insulating layer 360 may include a ferroelectric material. The ferroelectric material exhibits spontaneous electric dipoles (spontaneous polarization) due to a non-centrosymmetric charge distribution within unit cells of a crystallized material structure. In addition, the ferroelectric material has remnant polarization due to dipoles even in the absence of an external electric field. In addition, the polarization direction of the ferroelectric material may be switched in domain units by an external electric field. For example, the ferroelectric material may include a fluorite-based material such as hafnium oxide (HfO), zirconium oxide (ZrO), or hafnium-zirconium oxide (HfZrO), or a perovskite such as lead zirconate titanate (PZT), BaTiO₃, or PbTiO₃. The semiconductor device 300 including the ferroelectric material may be applied to, for example, nonvolatile memory devices.

The gate electrode 370 may be provided corresponding to the channel 315 of the substrate 310. The gate electrode 370 may include a conductive material such as a metal, a metal nitride, polysilicon, or a 2D conductive material.

The source electrode 351 is provided above the source region 311, and the drain electrode 352 is provided above the drain region 312. The source electrode 351 and the drain electrode 352 may each include a conductive material (e.g., a metal).

A first laminated structure including a metal silicide may be provided between the source electrode 351 and the source region 311, and a second laminated structure including a metal silicide may be provided between the drain electrode 352 and the drain region 312. Each of the first laminated structure and the second laminated structure may be the same as described above in the previous embodiments.

The first electrode structure may include a first amorphous silicon layer 321, a first metal silicide layer 331, and a first metal nitride layer 341 that are sequentially stacked on the source region 311. The second electrode structure may include a second amorphous silicon layer 322, a second metal silicide layer 332, and a second metal nitride layer 342 that are sequentially stacked on the drain region 312. Each of the first and second amorphous silicon layers 321 and 322 is the same as the amorphous silicon layer 120 of the laminated structure 100 described with reference to FIG. 1. Each of the first and second metal silicide layers 331 and 332 is the same as the metal silicide layer 130 of the laminated structure 100 described with reference to FIG. 1. Each of the first and second metal nitride layers 341 and 342 is the same as (or substantially similar to) the metal nitride layer 140 of the laminated structure 100 described with reference to FIG. 1. In addition, each of the first and second metal silicide layers 331 and 332 may have a single-layer structure or a multilayer structure.

As described above, the first laminated structure including a metal silicide is provided between the source electrode 351 and the source region 311, and the second laminated structure including a metal silicide is provided between the drain electrode 352 and the drain region 312. Thus, the contact resistance between the source electrode 351 and the source region 311, and the contact resistance between the drain electrode 352 and the drain region 312 may be reduced.

FIG. 16 is a view schematically illustrating a semiconductor device 400 according to at least one example embodiment. The semiconductor device 400 shown in FIG. 16 may be an FET.

Referring to FIG. 16, the semiconductor device 400 includes a substrate 410, a gate insulating layer 460, a gate electrode 470, a source electrode 451, and a drain electrode 452. The substrate 410 may include a semiconductor material. The substrate 410 may further include a dopant.

A channel 415 corresponding to the gate electrode 470 is formed in an upper portion of the substrate 410, and a source region 411 and a drain region 412 are respectively formed on both sides of the channel 415. The source electrode 451 is provided on the source region 411, and the drain electrode 452 is provided on the drain region 412.

The gate insulating layer 460 is provided on the channel 415 of the substrate 410, and the gate electrode 470 is provided on the gate insulating layer 460. The gate insulating layer 460 may include, for example, silicon oxide, silicon nitride, aluminum oxide, or the like. The gate insulating layer 460 may include a ferroelectric material. The gate electrode 470 may be provided corresponding to the channel 415 of the substrate 410. The gate electrode 470 may include a conductive material such as a metal, a metal nitride, polysilicon, or a 2D conductive material.

A metal wiring line 490 electrically connected to the gate electrode 470 is provided above the gate electrode 470. A laminated structure including a metal silicide is provided between the gate electrode 470 and the metal wiring line 490. The laminated structure may be the same as described above in the previous embodiments.

The electrode structure may include an amorphous silicon layer 420, a metal silicide layer 430, and a metal nitride layer 440 that are sequentially stacked on the gate electrode 470. The amorphous silicon layer 420 is the same as the amorphous silicon layer 120 of the laminated structure 100 described with reference to FIG. 1, and the metal silicide layer 430 is the same as the metal silicide layer 130 of the laminated structure 100 described with reference to FIG. 1. In addition, the metal nitride layer 440 is the same as the metal nitride layer 140 of the laminated structure 100 described with reference to FIG. 1.

As described above, the laminated structure including a metal silicide is provided between the gate electrode 470 and the metal wiring line 490, and thus, the contact resistance between the gate electrode 470 and the metal wiring line 490 may be reduced.

In at least some embodiments, the semiconductor device may include the first electrode structure and/or the second electrode structure of FIG. 15 and/or the electrode structure of FIG. 16.

While some embodiments have been described, the embodiments are merely examples, and it will be understood by those of ordinary skill in the art that various modifications and other equivalent embodiments may be made therein.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A laminated structure comprising:
an amorphous silicon layer;
a metal silicide layer on the amorphous silicon layer; and
a metal nitride layer on the metal silicide layer such that the metal silicide layer is between the metal nitride layer and the amorphous silicon layer.

2. The laminated structure of claim 1, wherein the metal silicide layer is a structure including one or more layers.

3. The laminated structure of claim 1, wherein the metal silicide layer comprises at least one of TiSiₓ, ZrSiₓ, MoSiₓ, WSiₓ, CoSiₓ, or NiSiₓ.

4. The laminated structure of claim 1, wherein the metal nitride layer comprises at least one of TiN, TaN, WN, or NbN.

5. The laminated structure of claim 1, wherein the amorphous silicon layer has a thickness of about 0.1 nanometers (nm) to about 50 nm.

6. The laminated structure of claim 1, wherein the metal silicide layer has a thickness of about 0.1 nanometers (nm) to about 20 nm.

7. The laminated structure of claim 1, wherein the metal nitride layer has a thickness of about 0.1 nanometers (nm) to about 10 nm.

8. The laminated structure of claim 1, further comprising:
a first material layer on a lower surface of the amorphous silicon layer; and
a second material layer on an upper surface of the metal nitride layer.

9. The laminated structure of claim 8, wherein the first material layer comprises at least one of a semiconductor material or a metal.

10. The laminated structure of claim 1, wherein the metal nitride layer comprises oxygen.

11. A method of manufacturing a laminated structure, the method comprising:
depositing an amorphous silicon layer on a first material layer;
depositing a metal layer on the amorphous silicon layer;
depositing a metal nitride layer on the metal layer; and
forming a metal silicide layer between the amorphous silicon layer and the metal nitride layer by forming a compound of a metal of the metal layer and silicon of the amorphous silicon layer using a heat treatment process.

12. The method of claim 11, wherein the depositing the metal layer is performed in situ on the amorphous silicon layer, and the depositing the metal nitride layer is performed in situ on the metal layer.

13. The method of claim 11, wherein the heat treatment process is performed at a temperature of 500° C. or higher.

14. The method of claim 11, wherein the first material layer comprises at least one of a semiconductor material or a metal.

15. The method of claim 11, further comprising:
forming a second material layer on the metal nitride layer.

16. The method of claim 15, wherein the second material layer comprises a metal.

17. A semiconductor device comprising:
a semiconductor layer comprising silicon;
an amorphous silicon layer on the semiconductor layer;
a metal silicide layer on the amorphous silicon layer;
a metal nitride layer on the metal silicide layer such that the metal silicide layer is between the metal nitride layer and the amorphous silicon layer; and
a metal layer on the metal nitride layer such that the metal nitride layer is between the metal layer and the metal silicide layer.

18. The semiconductor device of claim 17, wherein the semiconductor layer comprises a source region or a drain region, and
the metal layer comprises a source electrode or a drain electrode.

19. The semiconductor device of claim 17, wherein the semiconductor layer comprises a gate electrode, and
the metal layer comprises a metal wiring line.

20. The semiconductor device of claim 17, wherein the metal silicide layer comprises at least one of TiSiₓ, ZrSiₓ, MoSiₓ, WSiₓ, CoSiₓ, or NiSiₓ.
